(19) United States
(12) Patent Application Publication
(10) Pub. No.: US 2026/0333852 A1
(43) Pub. Date: Oct. 22, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Sheng-Syun WONG, Hsinchu (TW)

(21) Appl. No.: 19/281,319

(22) Filed: Jul. 25, 2025

Related U.S. Application Data
(60) Provisional application No. 63/790,888, filed on Apr. 18, 2025.

(51) Int. Cl. H10D 84/83; H10D 30/00; H10D 30/01; H10D 30/43; H10D 62/10; H10D 62/13; H10D 62/60; H10D 62/832; H10D 62/834; H10D 84/01

(52) U.S. Cl. CPC H10D 84/832; H10D 30/014; H10D 30/0191; H10D 30/43; H10D 30/502; H10D 62/102; H10D 62/116; H10D 62/121; H10D 62/151; H10D 62/60; H10D 62/832; H10D 62/834; H10D 84/013

(57) ABSTRACT

Embodiments of the present disclosure provide semiconductor device structures and methods of forming the same. The structure includes a source/drain region including a first semiconductor layer, a second semiconductor layer, and a third semiconductor layer, and the first semiconductor layer includes an undoped binary semiconductor material, the second semiconductor layer and the third semiconductor layer include a doped single semiconductor material. A dopant concentration of the second semiconductor layer is different from a dopant concentration of the third semiconductor layer, and a thickness of the source/drain region is different from a width of the source/drain region in a cross-sectional view. The structure further includes an interposing layer disposed below the source/drain region, a fourth semiconductor layer interfacing a side surface of the first semiconductor layer, a contact etch stop layer disposed over the source/drain region, and an interlayer dielectric (ILD) layer disposed over the contact etch stop layer.

### CROSS-REFERENCE TO RELATED APPLICATIONS

This application claims priority to U.S. Provisional Application Ser. No. 63/790,888 filed on Apr. 18, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 are perspective views of various stages of manufacturing a semiconductor device structure, in accordance with some embodiments.

FIGS. 9A, 10A, 10A-1, 10A-2, 11A, 12A, and 13A are cross-sectional side views of various stages of manufacturing the semiconductor device structure taken along the line A-A of FIG. 8, in accordance with some embodiments.

FIGS. 9B, 10B, 10B-1, 11B, 12B, and 13B are cross-sectional side views of various stages of manufacturing the semiconductor device structure taken along the line B-B of FIG. 9A, in accordance with some embodiments.

FIGS. 14A, 14B, and 14C are cross-sectional side views of one of various stages of manufacturing the semiconductor device structure taken along the line C-C of FIG. 8, in accordance with some embodiments.

FIGS. 15 and 16 are cross-sectional side views of various stages of manufacturing the semiconductor device structure taken along the line A-A of FIG. 8, in accordance with some embodiments.

FIG. 17 is a cross-sectional side view of one of various stages of manufacturing the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

While the embodiments of this disclosure are discussed with respect to nanostructure channel FETs, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

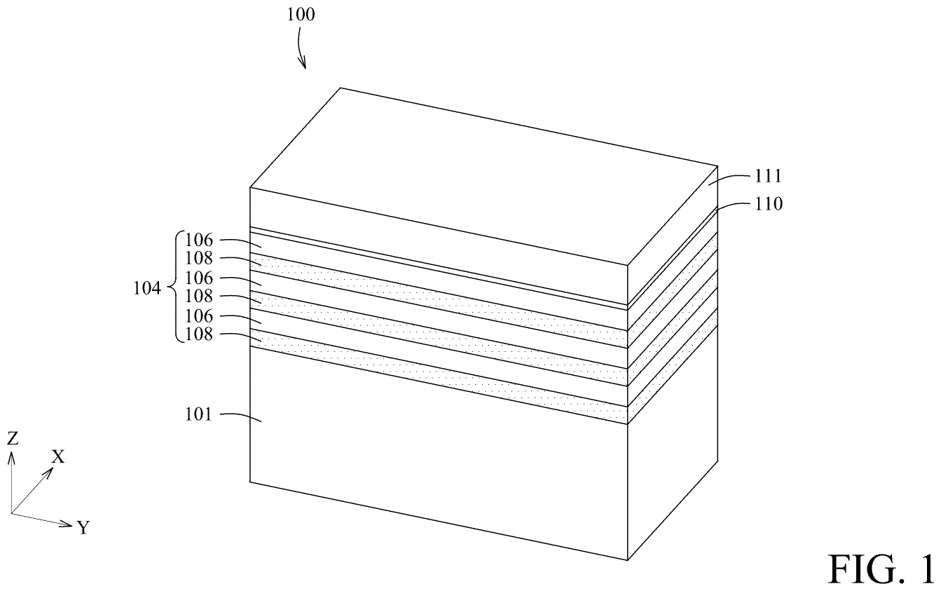

FIGS. 1 to 17 show exemplary processes for manufacturing a semiconductor device structure 100 according to embodiments of the present disclosure. It is understood that additional operations can be provided before, during, and after processes shown by FIGS. 1 to 17, and some of the operations described below can be replaced or eliminated, for additional embodiments of the method. The order of the operations/processes is not limiting and may be interchangeable.

FIGS. 1 to 8 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

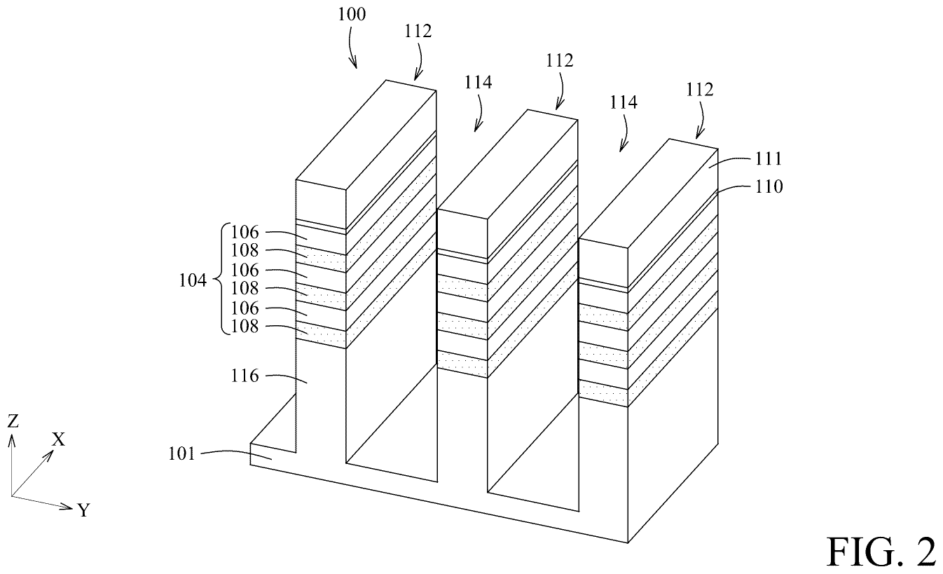

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

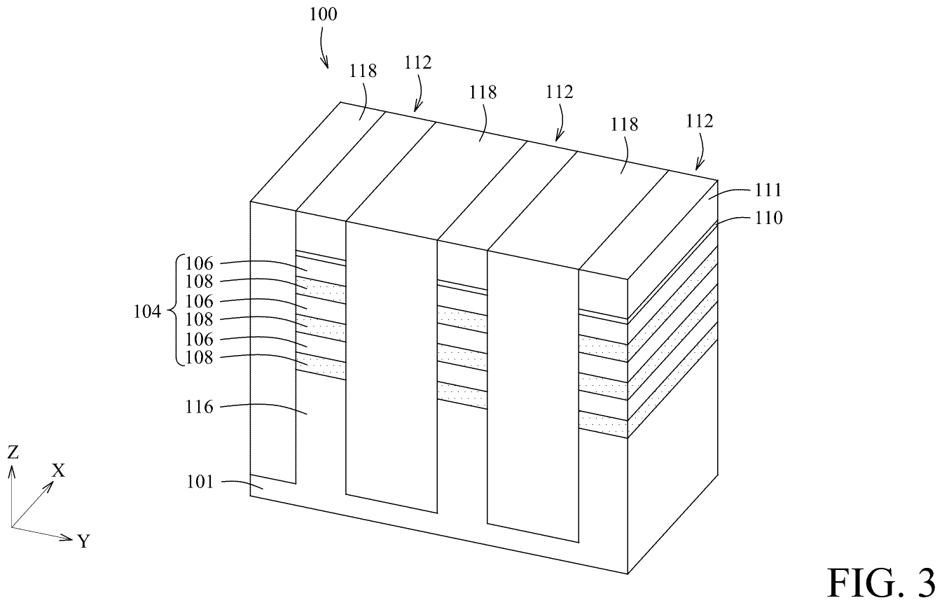

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

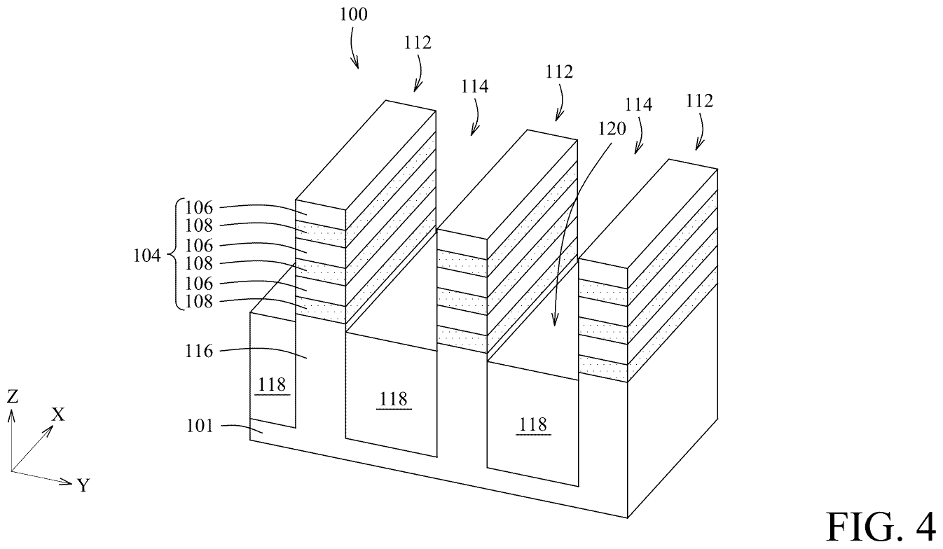

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

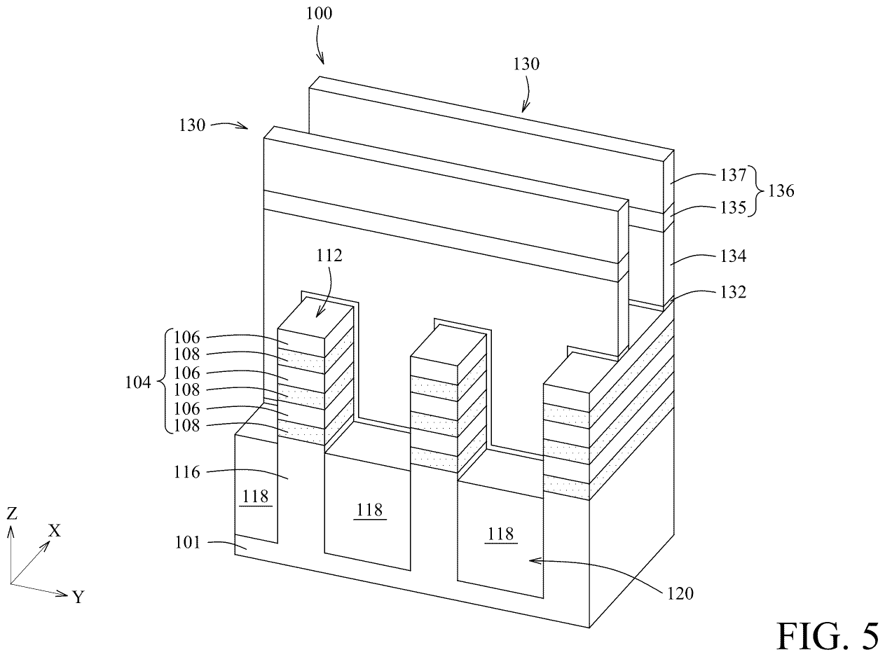

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

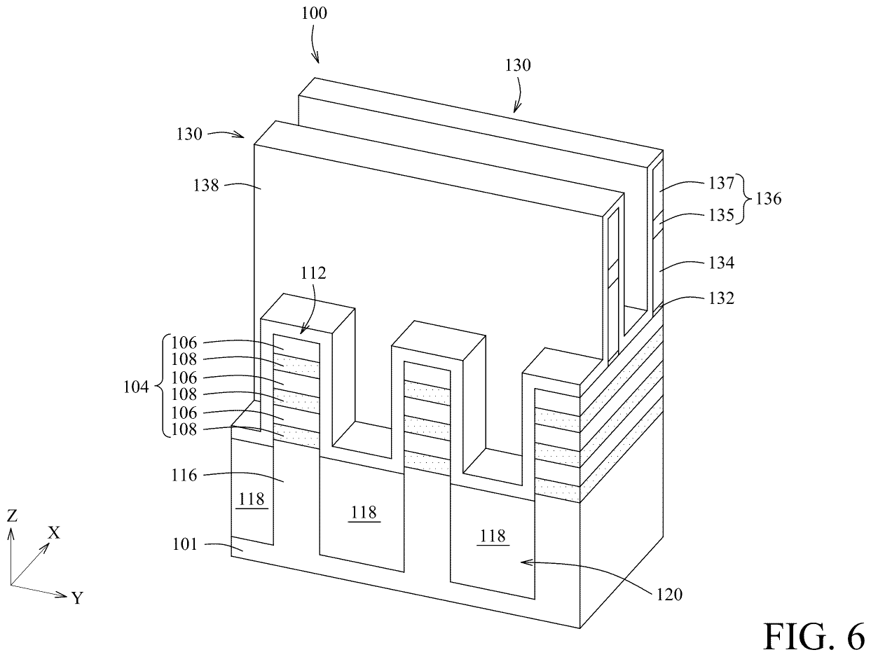

In FIG. 6, a spacer layer 138 is formed to cover the sacrificial gate structures 130, the second portions of the fin structures 112, and the second portions of the isolation regions 120. The spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the spacer layer 138 is formed by a conformal process, such as an atomic layer deposition (ALD) process.

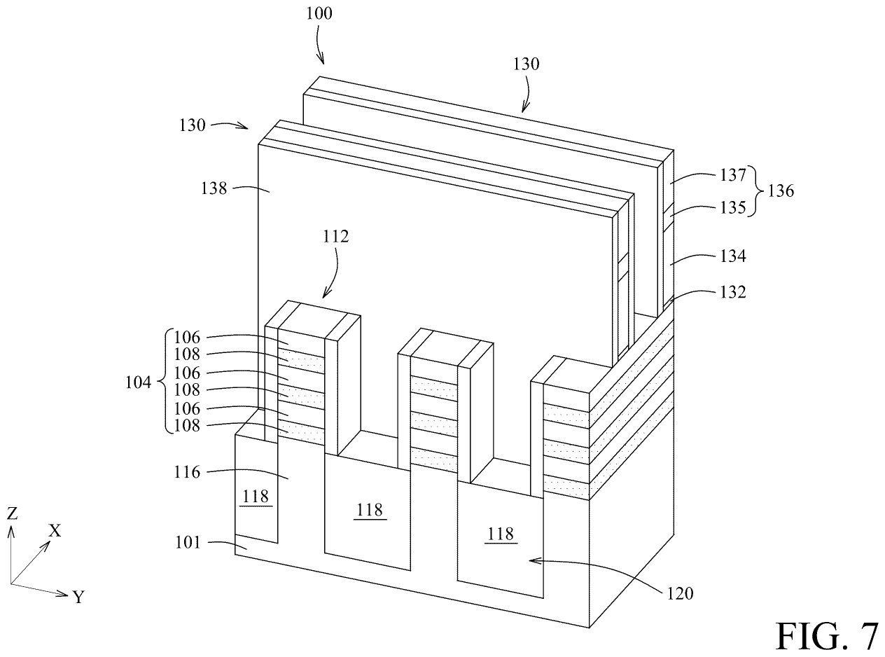

In FIG. 7, an anisotropic etch process is performed to remove horizontal portions of the spacer layer 138. The anisotropic etch process may be a selective etch process that does not substantially affect the nitride layer 137, the first semiconductor layer 106, and the isolation region 120. As a result, the second portions of the fin structures 112 are exposed.

In FIG. 8, one or more etch processes are performed to recess the exposed second portions of the fin structures 112 not covered by the sacrificial gate structures 130 (and the portions of the spacer layer 138 formed on sidewalls of the sacrificial gate structures 130) and to remove portions of the spacer layer 138. The portions of the spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form spacers 140 including a first portion 140a formed on sidewalls of the sacrificial gate electrode layer 134 and second portions 140b formed on the second portions of the isolation regions 120. In some embodiments, the one or more etch processes remove the portions of the spacer layer 138 formed on the second portions of the isolation regions 120. In other words, the second portions 140b of the spacer 140 are not present, in some embodiments. In some embodiments, the one or more etch processes also remove portions of the second portions of the isolation regions 120, as shown in FIG. 8. As a result, the top surface 120t of the second portion of the isolation region 120 is located at a level substantially below the top surface 116t of the substrate portion 116. The recessing of the exposed second portions of the fin structures 112 form trenches 131 between adjacent stacks of semiconductor layers 104, as shown in FIG. 8.

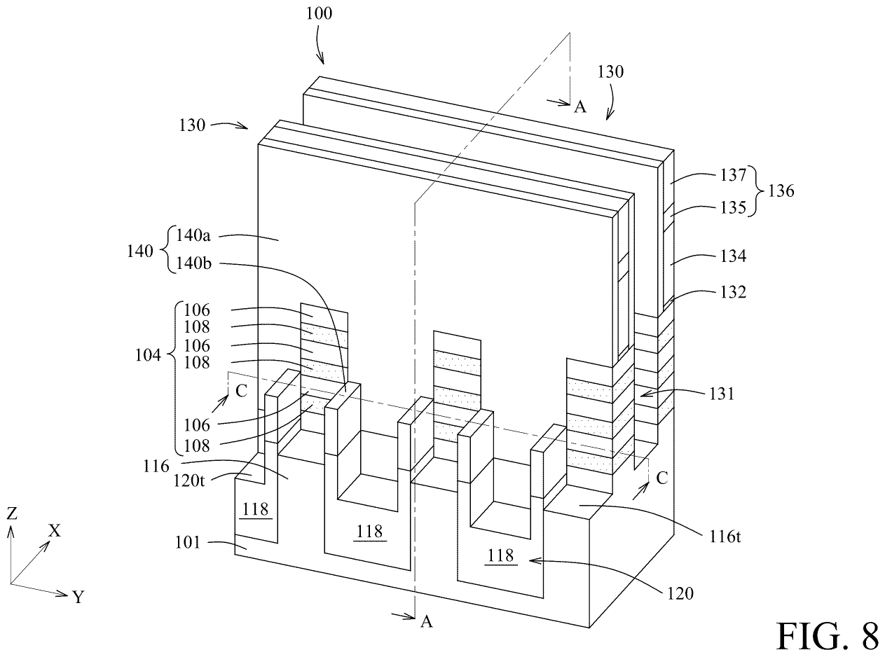

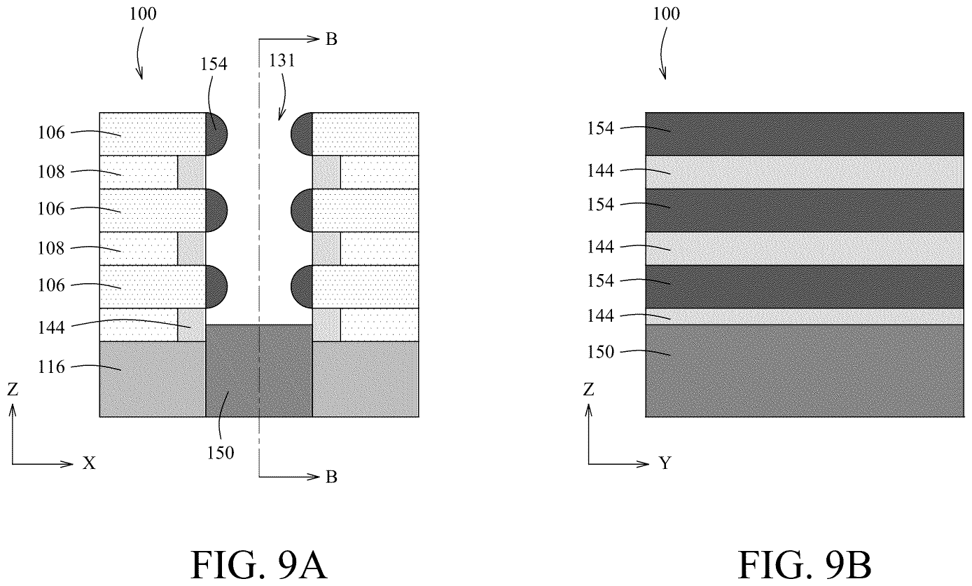

FIGS. 9A, 10A, 11A, 12A, and 13A are cross-sectional side views of various stages of manufacturing the semiconductor device structure taken along the line A-A of FIG. 8, and FIGS. 9B, 10B, 11B, 12B, and 13B are cross-sectional side views of various stages of manufacturing the semiconductor device structure taken along the line B-B of FIG. 9A, in accordance with some embodiments. As shown in FIGS. 9A and 9B, edge portions of each second semiconductor layer 108 of the stack of semiconductor layers 104 are removed horizontally along the X direction to form cavities, and dielectric spacers 144 are formed in the cavities. In some embodiments, the edge portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

In some embodiments, instead of laterally recessing the second semiconductor layers 108, the entire second semiconductor layers 108 are removed to create openings between vertically adjacent first semiconductor layers 106. A dielectric layer (not shown) is formed in the openings between the vertically adjacent first semiconductor layers 106, and the dielectric layer is laterally recessed to form cavities.

The dielectric spacers 144 may be formed by first depositing a dielectric layer (not shown) on the semiconductor device structure 100. The dielectric layer may be formed in the cavities. The dielectric layer may be made of a low-K dielectric material, such as SiO₂, SiON, SiCN, SiOC, SiOCN, or SiN. In some embodiments, the dielectric layer does not completely fill the cavities, and air gaps are formed. The dielectric layer may be deposited by any suitable process, such as CVD, PECVD, or ALD. In some embodiments, the dielectric layer is a conformal layer formed by a conformal deposition process, such as ALD. Next, an anisotropic etching process is performed to remove portions of the dielectric layer other than portions formed in the cavities, which are now the dielectric spacers 144. The dielectric spacers 144 are protected by the first semiconductor layers 106 during the anisotropic etching process. The remaining second semiconductor layers 108 are capped between the dielectric spacers 144 along the X direction. In some embodiments, the dielectric layer is capped between the dielectric spacers 144 along the X direction.

As shown in FIGS. 9A and 9B, an interposing layer 150 is formed on the exposed top surface of the substrate portion 116 (FIG. 8). The interposing layer 150 may be a semiconductor layer, a dielectric layer, or a combination thereof. In some embodiments, the interposing layer 150 includes undoped silicon or undoped SiGe. In some embodiments, the term undoped may include materials being unintentionally doped. For example, the interposing layer 150 may contain dopant diffused from other regions. In some embodiments, the interposing layer 150 is a dielectric layer including a dielectric material, such as SiN, SiON, or SiOCN. In some embodiments, the interposing layer 150 includes the undoped semiconductor layer and the dielectric layer disposed on the undoped semiconductor layer. The interposing layer 150 may function as an isolation to prevent leakage from subsequently formed S/D regions to the substrate portion 116.

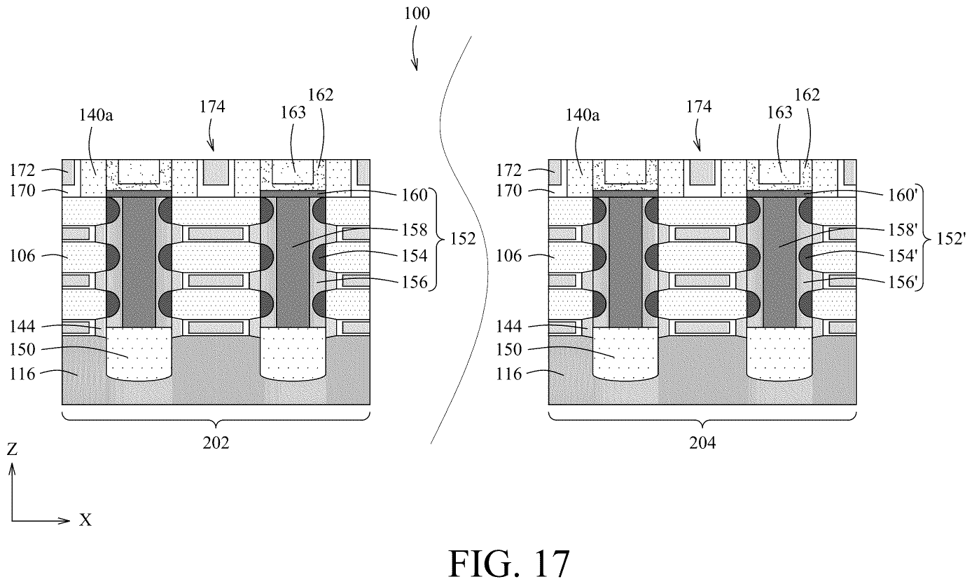

In some embodiments, regions of the semiconductor device structure 100 where n-type devices and p-type devices are formed are respectively referred to herein as “NMOS regions” and “PMOS regions.” For example, the semiconductor device structure 100 includes the NMOS region 202 and the PMOS region 204, as shown in FIG. 17. The S/D regions of the NMOS regions and PMOS regions are formed at different times. In some embodiments, after the formation of the interposing layer 150, a mask layer (not shown) is formed over the PMOS regions, while the NMOS regions are exposed. FIGS. 9A-13A and 9B-13B illustrate the processes to form S/D regions in the NMOS regions. As shown in FIGS. 9A and 9B, a first semiconductor layer 154 is formed from the first semiconductor layers 106. For example, the first semiconductor layer 154 may include a crystalline semiconductor material and is grown from the semiconductor material of the first semiconductor layers 106. The first semiconductor layer 154 may be formed by an epitaxial growth method using CVD, ALD or MBE. The first semiconductor layer 154 may be formed by a selective process and is not formed on dielectric materials. In some embodiments, the interposing layer 150 includes a semiconductor layer and a dielectric layer formed on the semiconductor layer. Thus, the first semiconductor layer 154 is not formed on the dielectric layer of the interposing layer 150. In some embodiments, the interposing layer 150 includes a semiconductor layer, and the first semiconductor layer 154 is also formed on the interposing layer 150.

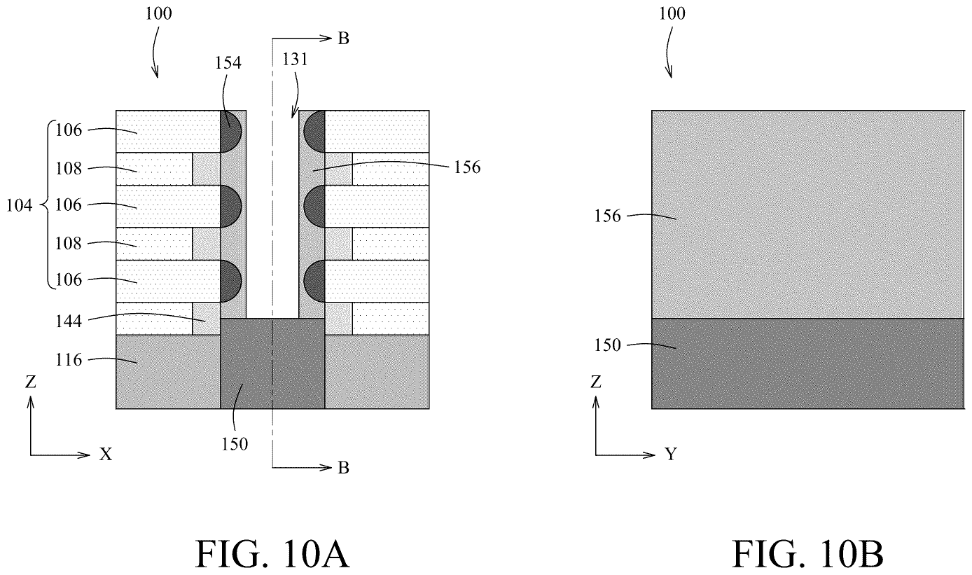

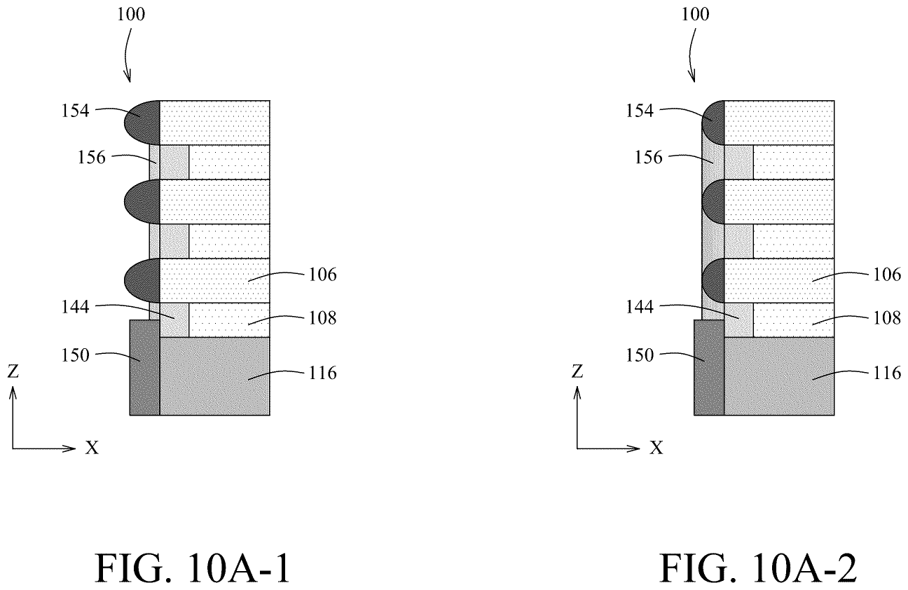

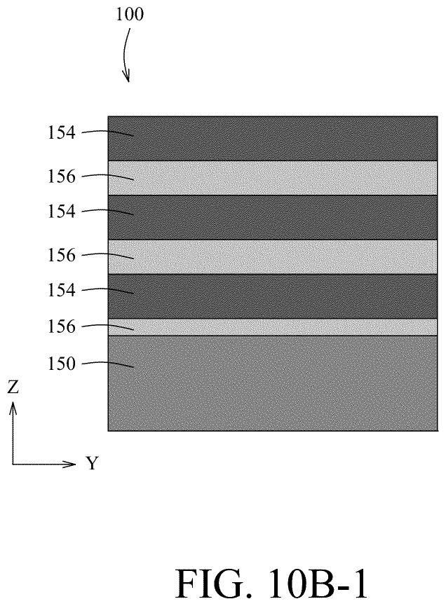

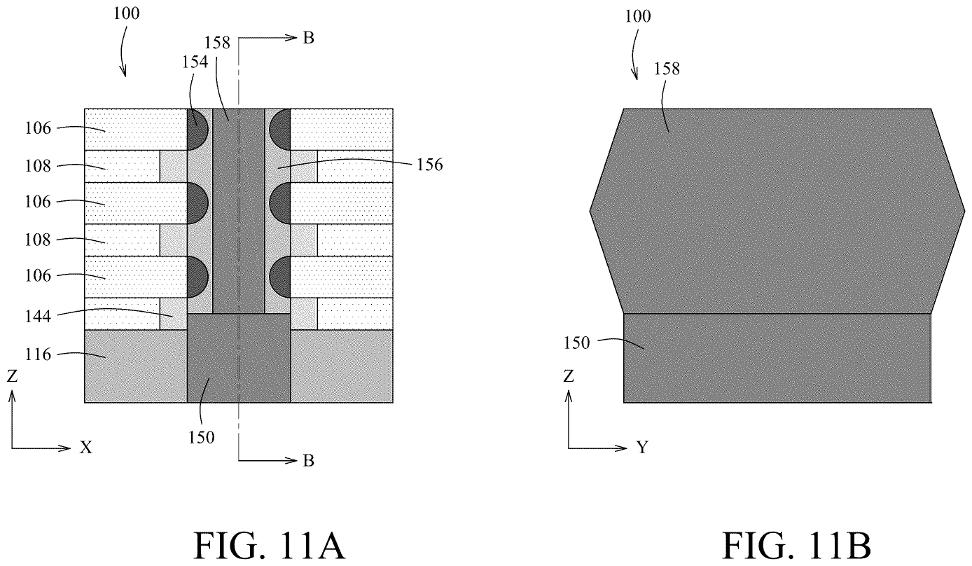

In some embodiments, the first semiconductor layer 154 includes a binary semiconductor material, such as SiAs. The first semiconductor layer 154 is not a doped semiconductor material, such as Si doped with As. The binary semiconductor material of the first semiconductor layer 154 can function as a blocking layer to prevent dopants in the subsequently formed semiconductor layers 156, 158 (FIGS. 10A and 11A) from diffusing into the first semiconductor layers 106. The doped semiconductor material, such as Si doped with As, may not function as a blocking layer to prevent the dopants from diffusing into the first semiconductor layers 106. In some embodiments, the As concentration of the first semiconductor layer 154 may range from about 1E21 atoms/cm³ to about 3E21 atoms/cm³. In some embodiments, the As concentration of the first semiconductor layer 154 may range from about two atomic percent (at%) to about six at %. If the concentration of As is less than the lower limits of the above-mentioned ranges, the first semiconductor layer 154 may not be able to block the diffusion of the dopants. On the other hand, if the concentration of As is greater than the upper limits of the above-mentioned ranges, the quality of the first semiconductor layer 154 may be negatively impacted. In some embodiments, other binary or tertiary semiconductor materials, such as GaAs, InAs, AlN, ZnSe, SiC, AlGaAs, InGaAs, AlInN, or AlGaN, may be used as the first semiconductor layer 154.

The first semiconductor layers 154 and the dielectric spacers 144 shown in FIG. 9B are located behind the plane defined by the line B-B of FIG. 9A. In other words, when the trench 131 is not filled, the sidewall of the trench 131 is shown in FIG. 9A.

Next, as shown in FIGS. 10A and 10B, a second semiconductor layer 156 is formed from the first semiconductor layer 154. The second semiconductor layer 156 may include a doped semiconductor material, such as a doped single semiconductor material. The material of the second semiconductor layer 156 is different from the material of the first semiconductor layer 154. In some embodiments, the second semiconductor layer includes Si with an n-type dopant, such as P or As. For example, the SiAs of the first semiconductor layer 154 is different from the Si of the second semiconductor layer 156. In some embodiments, the second semiconductor layer 156 includes P doped Si. The second semiconductor layer 156 may be formed by an epitaxial growth method using CVD, ALD or MBE. In some embodiments, the second semiconductor layer 156 is formed using a plurality of deposition and etch cycles, which may be referred to as a deposition-etch-deposition process. If the deposition-etch-deposition process is not performed, the second semiconductor layers 156 formed on the topmost first semiconductor layers 154 may merge, and a void may be formed in the trench 131. Thus, in some embodiments, the second semiconductor layers 156 are formed between vertically adjacent first semiconductor layers 156 by the deposition-etch-deposition process, as shown in FIG. 10A. In some embodiments, after the deposition-etch-deposition process, a thickness of the second semiconductor layer 156 along the X direction is greater than a thickness of the first semiconductor layer 154 along the X direction. Thus, each first semiconductor layer 154 is surrounded by the second semiconductor layer 156. As a result, the sidewall of the trench 131 is covered by the second semiconductor layer 156, as shown in FIG. 10B. In such embodiments, the etch process of the deposition-etch-deposition process may be an anisotropic etch process, and the side surface of the second semiconductor layer 156 exposed in the trench 131 may be substantially straight, as shown in FIG. 10A. The second semiconductor layer 156 formed adjacent one stack of semiconductor layers 104 is a continuous layer, as shown in FIG. 10A.

In some embodiments, the thickness of the second semiconductor layer 156 is less than the thickness of the first semiconductor layer 154, as shown in FIG. 10A-1. In such embodiments, the etch process of the deposition-etch-deposition process may be an isotropic etch process, and the isotropic etch process may be a selective process that etches the second semiconductor layer 156 but not the first semiconductor layer 154, as shown in FIG. 10A-1. In some embodiments, the side surface of the second semiconductor layer 156 is substantially straight, as shown in FIG. 10A-1. In some embodiments, the side surface of the second semiconductor layer 156 is curved, such as having a concave profile. In some embodiments, the side wall of the trench 131 includes alternating first and second semiconductor layers 154, 156, as shown in FIG. 10B-1.

In some embodiments, the thickness of the second semiconductor layer 156 is the same as the thickness of the first semiconductor layer 154, as shown in FIG. 10A-2. In such embodiments, the etch process of the deposition-etch-deposition process may be an anisotropic etch process, and the etch chemistry is selected to etch both the first and second semiconductor layers 154, 156. In some embodiments, the side wall of the trench 131 is flat and includes alternating first and second semiconductor layers 154, 156, as shown in FIGS. 10A-2 and 10B-1.

In some embodiments, the dopant concentration of the second semiconductor layer 156 ranges from about 1E21 atoms/cm³ to about 2.5E21 atoms/cm³. In some embodiments, the dopant concentration of the second semiconductor layer 156 may range from about two at % to about five at %. The second semiconductor layer 156 may serve as a buffer between the undoped first semiconductor layer 154 and the subsequently formed third semiconductor layer 158 (FIG. 11A), which has a higher dopant concentration compared to the second semiconductor layer 156, to reduce current leakage. The higher dopant concentration of the third semiconductor layer 158 leads to increased electrical conductivity compared to the second semiconductor layer 156. Thus, if the dimensions of the second semiconductor layer 156 are large, the current leakage may be improved, while the overall electrical conductivity of the second and third semiconductor layers 156, 158 may be reduced. If the dimensions of the second semiconductor layer 156 are small, the current leakage may be worsen, while the overall electrical conductivity of the second and third semiconductor layers 156, 158 may be increased. The different thicknesses of the second semiconductor layers 156 shown in FIGS. 10A, 10A-1, and 10A-2 can be chosen to achieve different results. For example, if less current leakage is more important, the thickness of the second semiconductor layer 156 may be large, as shown in FIG. 10A. If electrical conductivity is more important, the thickness of the second semiconductor layer 156 may be small, as shown in FIG. 10A-1, so the overall electrical conductivity of the second and third semiconductor layers 156, 158 is improved. The structure shown in FIG. 10A-2 may be used, if a balanced current leakage versus electrical conductivity is sought.

As shown in FIGS. 11A and 11B, the third semiconductor layer 158 is formed from the second semiconductor layer 156 (or from both first and second semiconductor layers 154, 156). The third semiconductor layer 158 fills the trench 131. The third semiconductor layer 158 may include any suitable semiconductor material. In some embodiments, the third semiconductor layer 158 includes the same material as the second semiconductor layer 156, except that the dopant concentration of the third semiconductor layer 158 is greater than the dopant concentration of the second semiconductor layer 156. In some embodiments, the dopant concentration of the third semiconductor layer 158 ranges from about 3E21 atoms/cm³ to about 4.5E21 atoms/cm³. In some embodiments, the dopant concentration of the third semiconductor layer 158 may range from about six at % to about nine at %. As described above, the higher dopant concentration of the third semiconductor layer 158 can lead to increased electrical conductivity. In some embodiments, the third semiconductor layer 158 grow both vertically and horizontally to form facets, which may correspond to crystalline planes of the material used for the second semiconductor layer 156, as shown in FIG. 11B.

In some embodiments, the thickness of the second semiconductor layer 156 is greater than the thickness of the first semiconductor layer 154, and the third semiconductor layer 158 interfaces the second semiconductor layer 156. In some embodiments, the thickness of the second semiconductor layer 156 is the same as or less than the thickness of the first semiconductor layer 154, and the third semiconductor layer 158 interfaces the first and second semiconductor layers 154, 156.

In some embodiments, the thickness of the second semiconductor layer 156 along the X direction or the thickness of the first semiconductor layer 154 along the X direction is less than a thickness of the third semiconductor layer 158 along the X direction. The thicker third semiconductor layer 158 can lead to increased overall electrical conductivity, because the third semiconductor layer 158 has higher dopant concentration than that of the second or first semiconductor layers 156, 154.

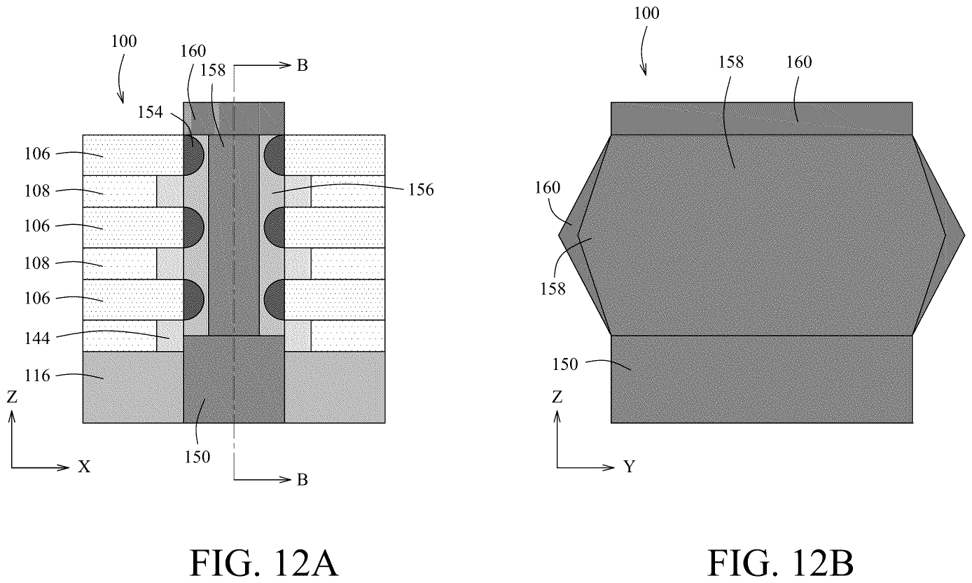

Next, as shown in FIGS. 12A and 12B, a fourth semiconductor layer 160 is formed around the third semiconductor layer 158. The third semiconductor layer 160 may include the material of the first semiconductor layer 154 in order to prevent the diffusion of the dopant out of the third semiconductor layer 158. In some embodiments, the fourth semiconductor layer 160 includes SiAs having an As concentration ranging from about 1E21 atoms/cm³ to about 3E21 atoms/cm³. In some embodiments, the As concentration of the fourth semiconductor layer 160 ranges from about two at % to about six at %. If the As concentration of the fourth semiconductor layer 160 is less than the lower limits of the above-mentioned ranges, the fourth semiconductor layer 160 may not effectively block the dopants in the second and third semiconductor layers 156, 158 from migrating therethrough. As a result, the dopant concentration in the second and third semiconductor layers 156, 158 may be reduced, which may increase the resistance of the second and third semiconductor layers 156, 158. On the other hand, if the As concentration of the fourth semiconductor layer 160 is greater than the upper limits of the above-mentioned ranges, defects in the fourth semiconductor layer 160 may arise.

In some embodiments, the fourth semiconductor layer 160 is undoped. In some embodiments, the fourth semiconductor layer 160 is doped with an n-type dopant, such as P or As. In some embodiments, the fourth semiconductor layer 160 includes SiAs doped with P. The dopant concentration of the fourth semiconductor layer 160 may range from about 0 atoms/cm³ to about 3E21 atoms/cm³. In some embodiments, the dopant concentration of the fourth semiconductor layer 160 ranges from about 0 at % to about six at %. The dopant in the fourth semiconductor layer 160 may increase the electrical conductivity. However, if the dopant concentration of the fourth semiconductor layer 160 is greater than the upper limits of the above-mentioned ranges, the fourth semiconductor layer 160 may be etched at a faster rate during a subsequent etching back process. As a result, the third semiconductor layer 158 may be damaged by the etching back process.

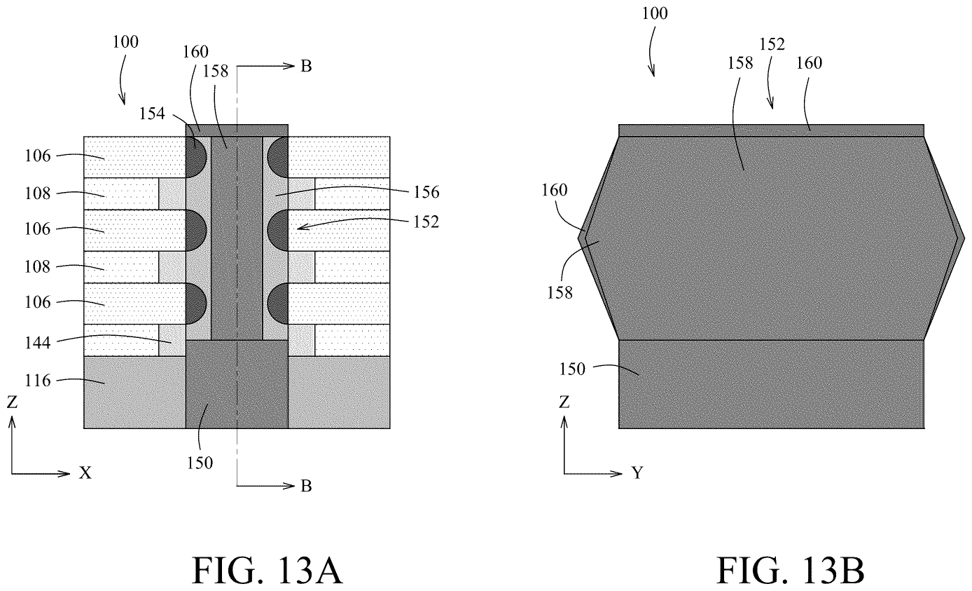

In some embodiments, as shown in FIG. 12B, the fourth semiconductor layer 160 is formed on the facets of the third semiconductor layer 158, and the adjacent fourth semiconductor layers 160 along the Y direction may merge. The merged fourth semiconductor layer 160 can lead to NFETs short defect. In some embodiments, in order to remove the merged portion of the adjacent fourth semiconductor layers 160, an etching back process is performed. As shown in FIGS. 13A and 13B, portions of the fourth semiconductor layer 160 are removed by the etching back process. In some embodiments, the etching back process is performed at a high temperature, such as from about 650 degrees Celsius to about 900 degrees Celsius. The high temperature etching back process ensures the removal of the merged portion of the adjacent fourth semiconductor layers 160 without over-etching the fourth semiconductor layer 160 and damaging the third semiconductor layer 158. At such high temperature, the dopants can diffuse out of the second and third semiconductor layers 156, 158, if the first and fourth semiconductor layers 154, 160 are not present. With reduced dopant concentration in the second and third semiconductor layers 156, 158, the electrical conductivity of the second and third semiconductor layers 156, 158 may be reduced. Thus, by having the first and fourth semiconductor layers 154, 160, the dopant concentrations of the second and third semiconductor layers 156, 158 are not reduced during the high temperature etching back process. In some embodiments, the first, second, third, and fourth semiconductor layers 154, 156, 158, 160 form a source/drain (S/D) region 152. The S/D region 152 may be an n-type S/D region 152. In this disclosure, a source region and a drain region are interchangeably used, and the structures thereof are substantially the same. Furthermore, source/drain region(s) may refer to a source or a drain, individually or collectively dependent upon the context.

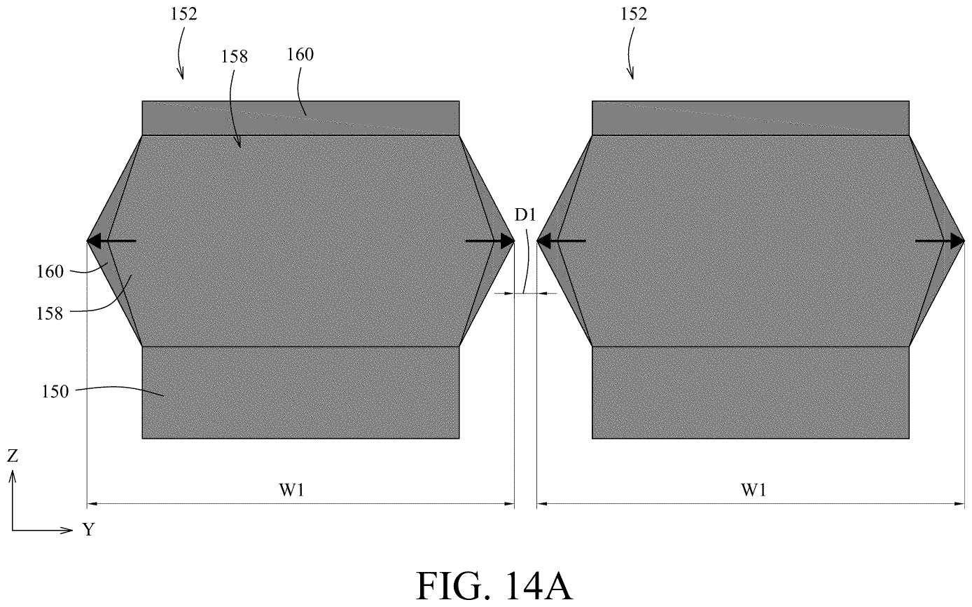

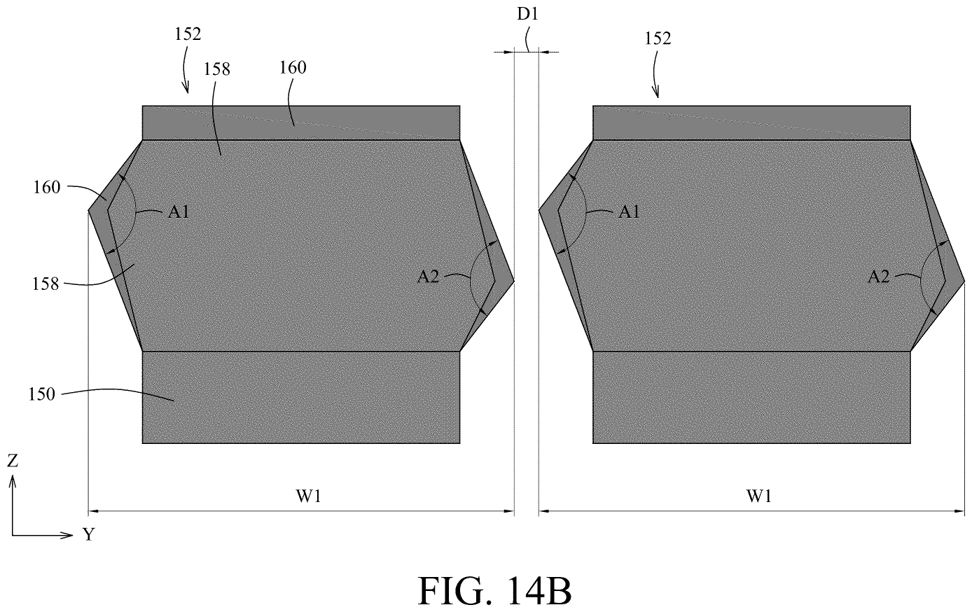

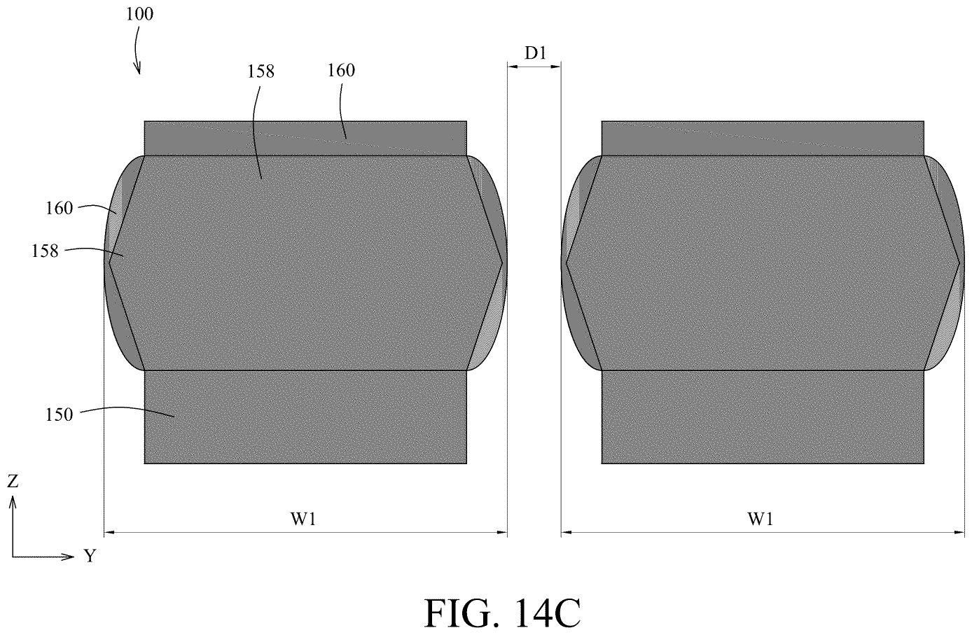

FIGS. 14A, 14B, and 14C are cross-sectional side views of one of various stages of manufacturing the semiconductor device structure 100 taken along the line C-C of FIG. 8, in accordance with some embodiments. As shown in FIG. 14A, the adjacent n-type S/D regions 152 are separated by a distance D1 as a result of the etching back process. In some embodiments, the distance D1 ranges from about 0.1 nm to about 5.0 nm. The portion of the fourth semiconductor layer 160 located on the top surface of the third semiconductor layer 158 has a thickness along the Z direction ranging from about 2.0 nm to about 9.0 nm. In some embodiments, the S/D region 152 may have a width W1 ranging from about 30.0 nm to about 55.0 nm. In some embodiments, the thickness of the S/D region 152 along the Z direction is different from the width W1. In some embodiments, an angle A1 is formed by the facets on a first side of the S/D region 152, and an angle A2 is formed by the facets on a second side opposite the first side of the S/D region 152, as shown in FIG. 14A. The angles A1, A2 may range from about 70 degrees to about 170 degrees. In some embodiments, the angles A1, A2 are the same. In some embodiments, the angles A1, A2 are different.

In some embodiments, the facets formed on opposite sides of the S/D region 152 may be asymmetrical, as shown in FIG. 14B. The S/D region 152 with asymmetrical facets may be the result of the formation of the third and fourth semiconductor layers 158, 160 and/or the etching back process. In some embodiments, as shown in FIG. 14C, the etching back process forms a smooth curved side surface of the S/D region 152. In some embodiments, the curved side surface is the side surface of the fourth semiconductor layer 160. In some embodiments, the curved side surface is a combination of the side surfaces of the third and fourth semiconductor layers 158, 160.

After the formation of the n-type S/D regions 152, a mask layer (not shown) is formed in the NMOS regions, and the mask layer formed in the PMOS regions is removed. S/D regions may be then formed in the PMOS region. In some embodiments, there is no dopant diffusion issue in the PMOS region. As a result, as shown in FIG. 17, an S/D region 152′ located in the PMOS region 204 includes a first semiconductor layer 154′, a second semiconductor layer 156′, a third semiconductor layer 158′, and a fourth semiconductor layer 160′. In some embodiments, the first semiconductor layer 154′ may include a doped semiconductor material, such as Si or SiGe doped with a p-type dopant, such as B. The second semiconductor layer 156′ may include the same material and composition as the first semiconductor layer 154′ but with a higher dopant concentration. The third semiconductor layer 158′ may include the same material and composition as the second semiconductor layer 156′ but with a higher dopant concentration. The fourth semiconductor layer 160′ may include the same material and composition as the third semiconductor layer 158′ but with a lower dopant concentration. Thus, in some embodiments, the semiconductor layers of the NMOS region 202 include different semiconductor materials, while the semiconductor layers of the PMOS region 204 include the same semiconductor materials but with different dopant concentration.

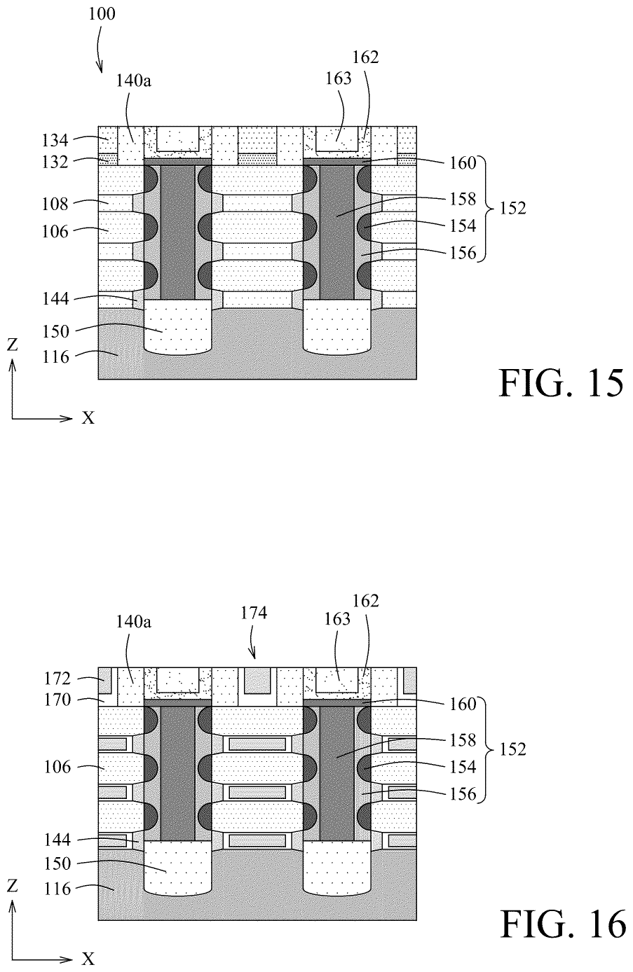

FIGS. 15 and 16 are cross-sectional side views of various stages of manufacturing the semiconductor device structure 100 taken along the line A-A of FIG. 8, in accordance with some embodiments. After forming the S/D regions 152 in the NMOS regions and the PMOS regions, a contact etch stop layer (CESL) 162 is conformally formed on the exposed surfaces of the semiconductor device structure 100, as shown in FIG. 15. The CESL 162 covers the sidewalls of the first portion 140a of the spacers 140 and is disposed on the S/D regions 152. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 15. The planarization process may be any suitable process, such as a CMP process. The planarization process removes portions of the ILD layer 163 and the CESL 162 disposed on the sacrificial gate structures 130.

As shown in FIG. 16, the sacrificial gate electrode layer 134, the sacrificial gate dielectric layer 132, and the second semiconductor layers 108 are removed to expose portions of the first semiconductor layers 106, and a gate dielectric layer 170 and a gate electrode layer 172 are formed to surround the exposed portions of the first semiconductor layers 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 140, the ILD layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 140, the ILD layer 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

As shown in FIG. 16, the gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. The IL may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed, as shown in FIG. 16.

FIG. 17 is a cross-sectional side view of one of various stages of manufacturing the semiconductor device structure 100, in accordance with some embodiments. As described above, the semiconductor device structure 100 may include the NMOS region 202 and the PMOS region 204. The semiconductor layers 154, 160 of the NMOS region 202 include the binary semiconductor material to prevent out-diffusion of the dopants from the semiconductor layers 156, 158. The binary semiconductor material is different from the semiconductor material of the semiconductor layers 156, 158. In the PMOS region 204, the semiconductor layers 154′, 156′, 158′, 160′ include the same semiconductor material with different dopant concentrations, because there is no dopant out-diffusion issue in the PMOS region 204.

Embodiments of the present disclosure provide an n-type S/D region 152 includes a first semiconductor layer 154, a second semiconductor layer 156, a third semiconductor layer 158, and a fourth semiconductor layer 160. The first and fourth semiconductor layers 154, 160 include a binary semiconductor material to prevent out-diffusion of the dopants from the second and third semiconductor layers 156, 158. Some embodiments may achieve advantages. For example, by maintaining the dopant concentration in the second and third semiconductor layers 156, 158, the parasitic resistance of the S/D region 152 is reduced, and the electrical conductivity of the S/D region 152 is increased.

An embodiment is a method. The method includes forming a fin structure, and the fin structure includes a first semiconductor layer disposed over a substrate portion. The method further includes removing a portion of the fin structure to form a trench, and a side surface of the first semiconductor layer is exposed in the trench. The method further includes depositing a second semiconductor layer on the exposed side surface of the first semiconductor layer, and the second semiconductor layer includes a first semiconductor material. The method further includes depositing a third semiconductor layer around the second semiconductor layer, and the third semiconductor layer includes a second semiconductor material different from the first semiconductor material. The method further includes depositing a fourth semiconductor layer around and over the second and third semiconductor layer, performing an etching back process to remove portions of the fourth semiconductor layer, and forming an interlayer dielectric (ILD) layer over the fourth semiconductor layer.

Another embodiment is a method. The method includes forming a fin structure, and the fin structure includes a first semiconductor layer disposed over a substrate portion. The method further includes removing a portion of the fin structure to expose a side surface of the first semiconductor layer and depositing a second semiconductor layer on the exposed side surface of the first semiconductor layer. The second semiconductor layer includes an undoped binary semiconductor material. The method further includes depositing a third semiconductor layer around the second semiconductor layer, and the third semiconductor layer includes a doped single semiconductor material different from the undoped binary semiconductor material. The method further includes depositing a fourth semiconductor layer over the second and third semiconductor layers, and the fourth semiconductor layer includes a binary semiconductor material.

A further embodiment is a semiconductor device structure. The structure includes a source/drain region including a first semiconductor layer, a second semiconductor layer, and a third semiconductor layer, and the first semiconductor layer includes an undoped binary semiconductor material, the second semiconductor layer and the third semiconductor layer include a doped single semiconductor material. A dopant concentration of the second semiconductor layer is different from a dopant concentration of the third semiconductor layer, and a thickness of the source/drain region is different from a width of the source/drain region in a cross-sectional view. The structure further includes an interposing layer disposed below the source/drain region, a fourth semiconductor layer interfacing a side surface of the first semiconductor layer, a contact etch stop layer disposed over the source/drain region, and an interlayer dielectric (ILD) layer disposed over the contact etch stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure, wherein the fin structure comprises a first semiconductor layer disposed over a substrate portion;
removing a portion of the fin structure to form a trench, wherein a side surface of the first semiconductor layer is exposed in the trench;
depositing a second semiconductor layer on the exposed side surface of the first semiconductor layer, wherein the second semiconductor layer comprises a first semiconductor material;
depositing a third semiconductor layer around the second semiconductor layer, wherein the third semiconductor layer comprises a second semiconductor material different from the first semiconductor material;
depositing a fourth semiconductor layer around and over the second and third semiconductor layer;
performing an etching back process to remove portions of the fourth semiconductor layer; and
forming an interlayer dielectric (ILD) layer over the fourth semiconductor layer.

2. The method of claim 1, wherein a sidewall of the trench comprises the second and third semiconductor layers prior to the depositing of the fourth semiconductor layer.

3. The method of claim 1, wherein a sidewall of the trench comprises the third semiconductor layer prior to the depositing of the fourth semiconductor layer.

4. The method of claim 1, wherein a temperature of the etching back process ranges from about 650 degrees Celsius to about 900 degrees Celsius.

5. The method of claim 1, further comprising depositing a fifth semiconductor layer to fill the trench prior to the depositing of the fourth semiconductor layer.

6. The method of claim 5, wherein the fin structure further comprises sixth and seventh semiconductor layers disposed over the first semiconductor layer, wherein the second semiconductor layer is deposited on side surfaces of the sixth and seventh semiconductor layers.

7. A method, comprising:
forming a fin structure, wherein the fin structure comprises a first semiconductor layer disposed over a substrate portion;
removing a portion of the fin structure to expose a side surface of the first semiconductor layer;
depositing a second semiconductor layer on the exposed side surface of the first semiconductor layer, wherein the second semiconductor layer comprises an undoped binary semiconductor material;
depositing a third semiconductor layer around the second semiconductor layer, wherein the third semiconductor layer comprises a doped single semiconductor material different from the undoped binary semiconductor material; and
depositing a fourth semiconductor layer over the second and third semiconductor layers, wherein the fourth semiconductor layer comprises a binary semiconductor material.

8. The method of claim 7, wherein the undoped binary semiconductor material comprises SiAs, and the doped single semiconductor material comprises Si doped with P.

9. The method of claim 7, wherein the fin structure further comprises a fifth semiconductor layer disposed over the first semiconductor layer and a sixth semiconductor layer disposed below the first semiconductor layer.

10. The method of claim 9, wherein side surfaces of the fifth and sixth semiconductor layers are exposed by the removal of the portion of the fin structure.

11. The method of claim 10, wherein the second semiconductor layer is deposited on the exposed side surfaces of the fifth and sixth semiconductor layers.

12. The method of claim 11, further comprising a dielectric spacer interfacing the third semiconductor layer.

13. The method of claim 12, further comprising a gate structure surrounding the first, fifth, and sixth semiconductor layers, wherein the dielectric spacer is disposed between the gate structure and the third semiconductor layer.

14. The method of claim 7, wherein binary semiconductor material of the fourth semiconductor layer is undoped.

15. The method of claim 7, wherein the binary semiconductor material is doped.

16. A semiconductor device structure, comprising:
a source/drain region comprising a first semiconductor layer, a second semiconductor layer, and a third semiconductor layer, wherein the first semiconductor layer comprises an undoped binary semiconductor material, the second semiconductor layer and the third semiconductor layer comprise a doped single semiconductor material, a dopant concentration of the second semiconductor layer is different from a dopant concentration of the third semiconductor layer, and a thickness of the source/drain region is different from a width of the source/drain region in a cross-sectional view;
an interposing layer disposed below the source/drain region;
a fourth semiconductor layer interfacing a side surface of the first semiconductor layer;
a contact etch stop layer disposed over the source/drain region; and
an interlayer dielectric (ILD) layer disposed over the contact etch stop layer.

17. The semiconductor device structure of claim 16, further comprising a gate structure disposed around the fourth semiconductor layer.

18. The semiconductor device structure of claim 17, further comprising a dielectric spacer disposed between the gate structure and the second semiconductor layer.

19. The semiconductor device structure of claim 16, wherein the undoped binary semiconductor material comprises undoped SiAs.

20. The semiconductor device structure of claim 16, wherein the source/drain region further comprises a fifth semiconductor layer disposed over the third semiconductor layer, wherein the fifth semiconductor layer comprises a same material as the first semiconductor layer.
